(19) United States
(12) Patent Application Publication
(10) Pub. No.: US 2025/0286342 A1
(43) Pub. Date: Sep. 11, 2025

(54) EXTERNAL RESONATOR-TYPE LASER HAVING NARROW LINE WIDTH

(71) Applicant: PHOVEL Co., Ltd., Daejeon (KR)

(72) Inventor: Jeong Soo KIM, Sejong-si (KR)

(21) Appl. No.: 19/212,850

(22) Filed: May 20, 2025

Related U.S. Application Data
(63) Continuation of application No. PCT/KR2024/005126, filed on Apr. 17, 2024.

(30) Foreign Application Priority Data
Apr. 17, 2023 (KR) 10-2023-0050318
Apr. 16, 2024 (KR) 10-2024-0050951

(51) Int. Cl. H01S 5/024; H01S 5/02253; H01S 5/14

(52) U.S. Cl. CPC H01S 5/02446; H01S 5/02253; H01S 5/02415; H01S 5/14

(57) ABSTRACT

An external resonator-type laser having a narrow line width according to the present disclosure includes a gain chip having a laser gain, a lens for collimating light emitted from the gain chip into parallel light, and a wavelength selective filter for transmitting light having a specific wavelength among the light collimated through the lens, wherein two-sided heat transfer members disposed on at least one side of at least one of the lens and the wavelength selective filter and made of a material having a higher heat transfer rate than the lens and the wavelength selective filter, are included.

### CROSS-REFERENCE TO RELATED APPLICATIONS

This application is a Continuation of Application No. PCT/KR2024/005126, filed on Apr. 17, 2024, which in turn claims the benefit of Korean Patent Applications No. 10-2023-0050318, filed on Apr. 17, 2023, and No. 10-2024-0050951, filed on Apr. 16, 2024. The entire disclosures of all these applications are hereby incorporated by reference.

### TECHNICAL FIELD

The present disclosure relates to an external resonator-type laser, and more particularly, to an external resonator-type laser having a narrow line width capable of minimizing an oscillation line width of laser light by improving temperature uniformity of a wavelength selective filter and a lens in an external resonator-type laser.

### BACKGROUND ART

Recently, as a method of object recognition using lasers such as Lidar, a coherent signal processing method using a laser having a narrow line width is being utilized. In the coherent object recognition, a laser light source having a very narrow line width is required. The reason is that line width of the laser determines a coherent length, and the coherent length is directly related to a detection distance. Accordingly, the external resonator-type laser having a narrow line width has been developed and used.

FIG. 1 is a diagram for describing a conventional external resonator-type laser.

Referring to FIG. 1, as described in US Laid-Open Patent Publication No. US2003/0231666 A1, light spontaneously emitted from a gain chip 12 having a laser gain is collimated into parallel light through a lens 22 and transmits a wavelength selective filter 32. The light of the wavelength that transmits the wavelength selective filter 32 is reflected by a reflective mirror 14, transmits the wavelength selective filter 32 again, and then returns to the gain chip 12.

That is, a general structure of an external resonator-type laser that operates as a laser by causing the spontaneously emitted light generated from the gain chip 12 to be induced and emitted as laser light while transmitting the wavelength selective filter 32 is illustrated.

In the above process, light of a wavelength component that does not transmit the wavelength selective filter 32 in a spontaneous emission mode of the gain chip 12 is reflected by the wavelength selective filter 32 and reflected in a direction that does not return to the gain chip 12, and thus disappears without being returned to the gain chip 12. Accordingly, the external resonator-type laser composed of the gain chip 12, the wavelength selective filter 32, and the reflection mirror 14 oscillates only with the wavelength component that transmits the wavelength selective filter 32.

In this way, a single-mode external resonator-type laser is manufactured, and such a single-mode external resonator-type laser having a narrow line width is adopted and used in Lidar, etc.

FIG. 2 illustrates a heat transfer process in the external resonator-type laser arranged on the conventional thermoelectric cooler.

Referring to FIG. 2, a thermoelectric cooler 500 is a component used to maintain a temperature of components arranged above the thermoelectric cooler 500 at a constant level, and plays a role in heating or cooling an upper plate of the thermoelectric cooler depending on a direction and magnitude of an electric current. Since the entire component on which the thermoelectric cooler 500 is arranged is exposed to the external environmental temperature, the temperature of the outside of the thermoelectric cooler 500 and the upper plate of the thermoelectric cooler may vary, so the heat transfer originating from a part other than the thermoelectric cooler 500 may occur in the component arranged above the thermoelectric cooler 500.

The heat transfer from the outside of the thermoelectric cooler 500 is transferred (600) to the upper plate of the thermoelectric cooler by convection or radiation. Therefore, in the case of components (e.g., the gain chip 100, the lens 200, the wavelength selective filter 300, and the reflective mirror 400) arranged above the thermoelectric cooler 500, the direction in which heat is transferred from the upper plate of the lower thermoelectric cooler and the outside varies, so the temperature of the components arranged on the upper plate of the thermoelectric cooler varies depending on the position of the component itself (e.g., upper or lower). In this way, the internal temperature of the components placed on the upper plate of the thermoelectric cooler may become uneven depending on the position, which may cause the laser line width to increase.

FIG. 3 is a diagram for describing an operating principle of a conventional general Fabry-Perot type semiconductor laser.

The Fabry-Perot type semiconductor laser in FIG. 3 is a laser having a structure in which the wavelength selective filter 300 is excluded from the external resonator-type laser of FIG. 2.

Referring to FIG. 3, the external resonator type semiconductor laser is oscillated by the semiconductor gain chip 100 having gain characteristics that match semiconductor band gap characteristics, and oscillated in the oscillation laser mode of FIG. 3 by feedback amplification with a portion with a strong gain among Fabry-Perot modes of a resonator composed of the semiconductor gain chip 100 and the reflective mirror 400 (see the bottom drawing). Typically, the Fabry-Perot laser operates as a multi modelaser in which multiple oscillation peaks oscillate.

FIG. 4 is a diagram for describing an operating principle of the external resonator-type laser of FIG. 2.

The external resonator-type laser in FIG. 2 is a laser having a structure in which the wavelength selective filter 300 is additionally arranged in the laser of FIG. 3, and shows a single oscillation mode.

The additionally arranged wavelength selective filter 300 selectively transmits one of the Fabry-Perot modes and resonates within the resonator, so the external resonator-type laser has a single oscillation mode (see the bottom drawing).

FIGS. 5 and 6 are diagrams for describing the effect of temperature non-uniformity of a typical wavelength selective filter on the oscillating laser line width.

Referring to FIG. 5, the present embodiment is described based on the case where the wavelength selective filter is 0.5 mm wide, 1.5 mm high, and 1.5 mm high, heat (W) (e.g., 2 mW, 5 mW, 10 mW, 15 mW, and 20 mW) is uniformly generated on the upper surface thereof, the lower surface is at room temperature, and a material is glass, but is not limited thereto.

The wavelength selective filter is usually manufactured by a method of alternately depositing multiple materials with different permittivity on a substrate. Since all materials have different refractive indices depending on temperature, the temperature change at each location of the wavelength selective filter causes a change in a wavelength of light transmitting the wavelength selective filter.

In other words, since the direction of the heat applied to the wavelength selective filter 300 in the external resonator-type laser structure of FIG. 2 varies, the temperature non-uniformity occurs inside the wavelength selective filter.

FIG. 5 illustrates the temperature non-uniformity ‘A-C’ inside the wavelength selective filter when 2 mW, 5 mW, 10 mW, 15 mW, and 20 mW of heat are transferred to the upper portion of the wavelength selective filter. Regarding the heat transfer, the wavelength selective filter may exhibit a temperature difference of about 2.3 (Kelvin) to about 20° C. depending on the location (‘location A, location B, location C’).

Since the wavelength selective filter causes a wavelength change of 2 pm to 10 pm for a temperature difference of 1° C., a temperature difference of 20° C. may cause a transmission wavelength difference of 200 pm.

FIG. 6 illustrates a transmission wavelength curve according to the location of the wavelength selective filter, and it may be confirmed that the transmission wavelength changes depending on the temperature difference according to the locations ‘A, B, and C’ of the wavelength selective filter. In other words, even in one wavelength selective filter, if the temperature varies depending on the location, the difference in the wavelength of the light transmitted depending on the location may occur, which may cause a problem of increasing the line width.

In FIG. 6, the explanation is based on the wavelength selective filter, but in the case of the lens, when the temperature varies depending on the location, the wavelength of the light transmitted through the lens may vary.

FIG. 7 is a diagram the effect of the wavelength selective filter with non-uniform temperature on the oscillation characteristics of the external resonator-type laser.

Referring to FIG. 7, when the temperature varies depending on the locations ‘A and B’ of the wavelength selective filter, transmission characteristics 700 of the wavelength filter corresponding to ‘A’ and transmission characteristics 710 of the wavelength selective filter corresponding to ‘B’ may vary, so the oscillation characteristics of the external resonator-type laser may also experience a phenomenon in which the line width increases (720).

FIG. 8 is a diagram for describing the effect of the lens with non-uniform temperature on the oscillation characteristics of the external resonator-type laser.

The collimating lens 200 is usually made of glass material with a low heat transfer rate, and also undergoes heat exchange with the upper plate of the thermoelectric cooler at the lower portion and heat exchange with the outside air at the upper portion, so the temperature varies depending on the position of the lens, and accordingly, the optical length of the lens itself varies depending on the position. This is because an optical length of the lens is determined by a length of the lens along the optical path×a refractive index, and the refractive index is a function of temperature. Therefore, the optical length of each part of the lens varies depending on the temperature non-uniformity unlike when the temperature is uniform, which leads to the effect that the length of the optical path passing through each part of the lens varies slightly.

Referring to FIG. 8, when the temperature is different depending on the positions A′ and B′ of the lens, the optical path difference ('difference in the length of the optical path') occurs due to the change in the refractive index at each position of the lens, which may change the characteristics of the Fabry-Perot mode. For example, wavelength characteristics 800 of the allowed Fabry-Perot mode of the lens corresponding to ‘A’ and wavelength characteristics 810 of the allowed Fabry-Perot mode of the lens corresponding to ‘B’ may vary, so the phenomenon of increasing a line width 820 may also occur in the oscillation characteristics of the external resonator-type laser.

This application is the result of the national research and development project below.

### National Research and Development Project Supporting the Invention

[Project Identification Number] 1711193908

[Project Number] 2022-0-00523-003

[Department Name] Ministry of Science and ICT

[Project Management (Specialized) Agency Name] Institute of Information & Communications Technology Planning & Evaluation

[Research Project Name] Broadcasting and Communication Industry Technology Development

[Research Project Name] Development of 25Gbps-based 4-channel 100 Gbps NG-PON2+ Transceiver

[Project Execution Agency Name] Pobel Co., Ltd.

[Research Period] 2022 Apr. 1 to 2024 Dec. 31.

Prior literature related to this application includes US published patent US2003/0231666 (published on Dec. 18, 2003).

### DISCLOSURE

### Technical Problem

The present disclosure has been proposed to solve problems caused by oscillation characteristics of a conventional external resonator-type laser, and an object of the present disclosure provides an external resonator-type laser having a narrow line width capable of improving temperature uniformity of a wavelength selective filter and a lens of an external resonator-type laser.

### Technical Solution

In one general aspect, an external resonator-type laser having a narrow line width includes: a gain chip having a laser gain; a lens for collimating light emitted from the gain chip into parallel light; a wavelength selective filter for transmitting light having a specific wavelength among the light collimated through the lens; and two-sided heat transfer members disposed on at least one side of at least one of the lens and the wavelength selective filter and made of a material having a higher heat transfer rate than the lens and the wavelength selective filter.

The external resonator-type laser may further include an upper heat transfer member, which is arranged on an upper side surface of the lens and the wavelength selective filter and made of a material having the higher heat transfer rate than the lens and the wavelength selective filter.

The two-sided heat transfer members and the upper heat transfer member may be arranged to be spaced apart from the lens and the wavelength selective filter to form a space.

The external resonator-type laser may further include a lens fixing member coupled with the lens and has a structure that allows the lens to be erected in a vertical direction, in which the heat transfer member may be arranged on a side surface portion of the lens fixing member.

The heat transfer member may be made of a material having a heat transfer rate of 50 W/(m2° C.) or higher, and may be made of a semiconductor material including one of silicon (Si), gallium arsenide (GaAs), and germanium (Ge), or a metal material including one of aluminum (Al) and copper (Cu).

The heat transfer member may be attached through an epoxy mixed with powder including one or more of silver, copper, and carbon nanotube.

mAt least one of the gain chip, the lens, the wavelength selective filter, and the heat transfer member may be arranged in thermal contact with a thermoelectric cooler.

### Advantageous Effects

According to the present disclosure, by improving the temperature uniformity of the wavelength selective filter and the lens of the external resonator-type laser, the interference path may be lengthened, so it is possible to increase the measurement distance in the products that utilize interference of laser light such as Lidar.

### BRIEF DESCRIPTION OF THE DRAWINGS

FIG. 1 is a diagram for describing a conventional external resonator-type laser.

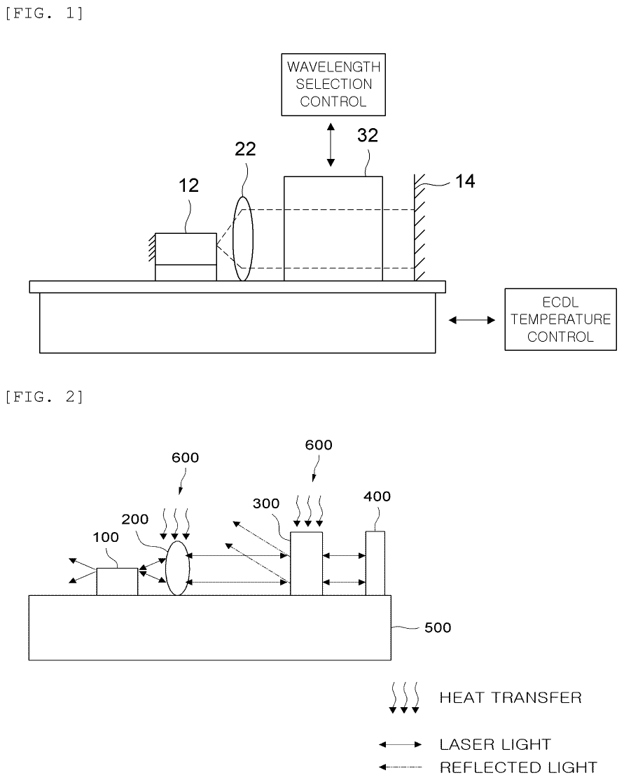

FIG. 2 is a diagram illustrating a heat transfer process in an external resonator-type laser arranged on a conventional thermoelectric cooler.

FIG. 3 is a diagram for describing an operating principle of a conventional general Fabry-Perot type semiconductor laser.

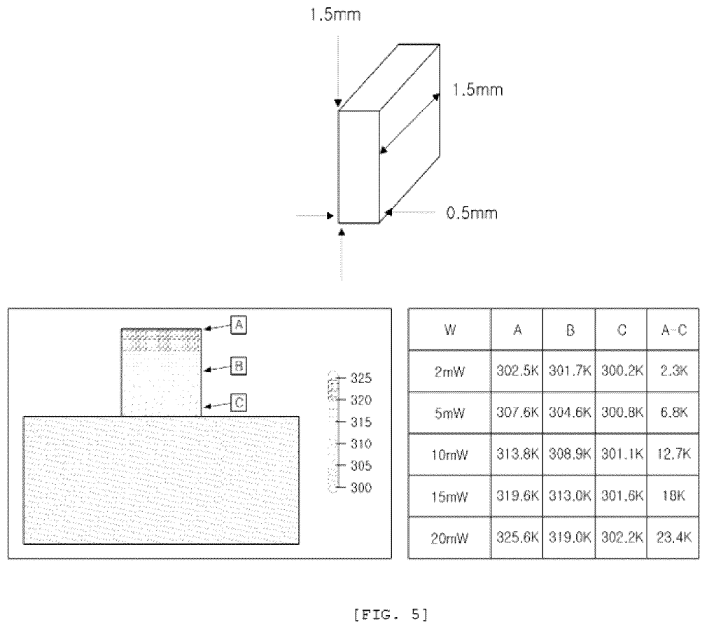

FIG. 4 is a diagram for describing the operating principle of the external resonator-type laser of FIG. 2.

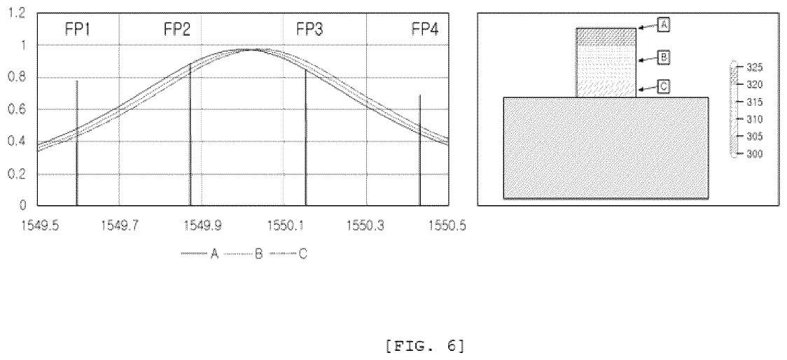

FIGS. 5 and 6 are diagrams for describing the effect of temperature non-uniformity of a typical wavelength selective filter on an oscillating laser line width.

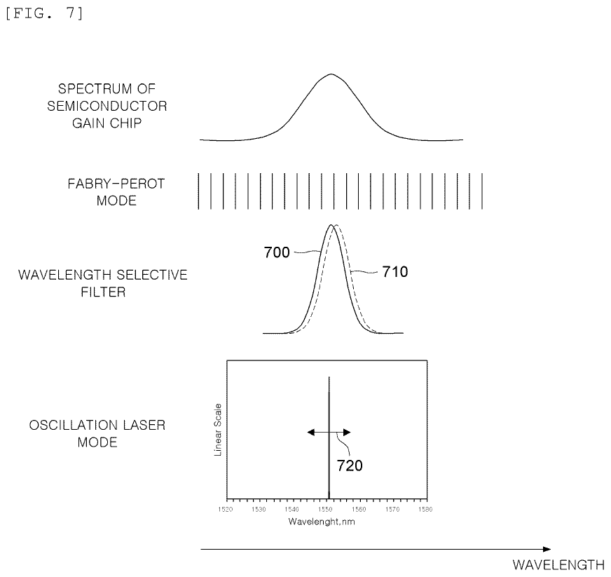

FIG. 7 is a diagram for describing the effect of the wavelength selective filter with non-uniform temperature on the oscillation characteristics of the external resonator-type laser.

FIG. 8 is a diagram for describing the effect of the lens with non-uniform temperature on the oscillation characteristics of the external resonator-type laser.

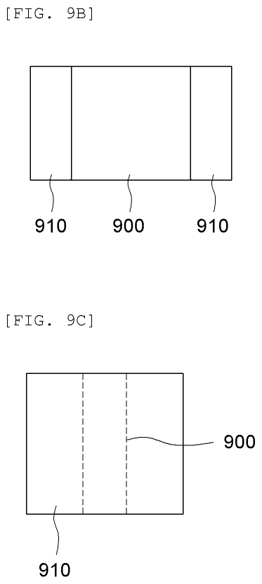

FIGS. 9A, 9B, 9C are diagrams for describing an external resonator-type laser including a heat transfer member arranged in a wavelength selective filter according to an embodiment of the present disclosure.

FIGS. 10A, 10B, 10C are diagrams for describing an external resonator-type laser including a heat transfer member arranged in a wavelength selective filter according to another embodiment of the present disclosure.

FIGS. 11A, 11B, 11C are diagrams for describing an external resonator-type laser including a heat transfer member arranged in a wavelength selective filter according to another embodiment of the present disclosure.

FIGS. 12A, 12B, 12C are diagrams for describing an external resonator-type laser including a heat transfer member arranged in a lens according to an embodiment of the present disclosure.

FIGS. 13A, 13B, 13C are diagrams for describing an external resonator-type laser including a heat transfer member arranged in a lens according to another embodiment of the present disclosure.

FIGS. 14A, 14B, 14C are diagrams for describing an external resonator-type laser including a heat transfer member arranged in a lens according to another embodiment of the present disclosure.

### BEST MODE

Hereinafter, detailed contents for embodying the present disclosure will be described in detail with reference to the accompanying drawings.

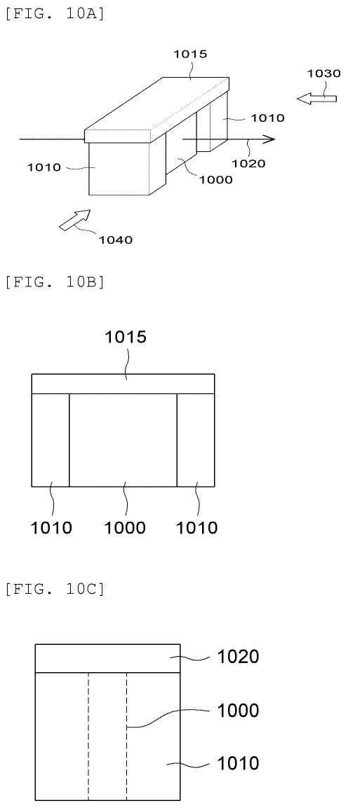

FIGS. 9A to 9C are diagrams for describing an external resonator-type laser including a heat transfer member arranged in a wavelength selective filter according to an embodiment of the present disclosure.

FIG. 9A is a perspective view of the wavelength selective filter and the heat transfer member, FIG. 9B is a front view of the wavelength selective filter and the heat transfer member as seen in a second direction 930 in FIG. 9A, and FIG. 9C is a side view of the wavelength selective filter and the heat transfer member as seen in a third direction 940 in FIG. 9A.

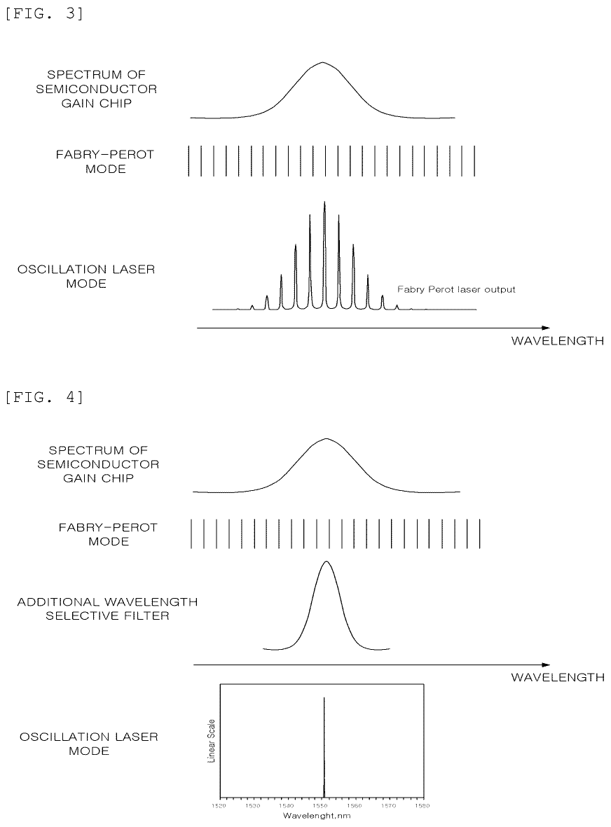

Referring to FIGS. 2, 9A, 9B, and 9C, light may transmit a wavelength selective filter 900 in a first direction 920.

The heat transfer member 910 may include a side heat transfer member 910. The side heat transfer member 910 is arranged on both side surfaces of the wavelength selective filter 900 other than the wavelength selective filter 900 surface in the first direction 920 which light transmits, and a lower side surface may be combined with the thermoelectric cooler 500 and may be a material having a higher heat transfer rate than the wavelength selective filter 900. By using a material having a high heat transfer rate, the heat transferred from the upper portion may be transferred to a lower portion through the heat transfer member 910 rather than the wavelength selective filter 900.

For example, when the wavelength selective filter 900 is made of a glass member and has a heat transfer rate of 1 W/(m²° C.), the heat transfer member 910 may be made of a material having a higher heat rate than the glass member. Examples of such materials include semiconductor materials such as a GaAs material, a germanium (Ge) material, and silicon, and metal materials such as AL and Cu. In addition, the heat transfer rate is 50 W/(m²° C.), and any material that may be attached may act as a member.

For example, a method of attaching the heat transfer member 910 to an outer circumferential surface of the wavelength selective filter 900 may use epoxy containing powders such as silver, copper, and carbon nano tube. The heat transfer member 910 should be thermally coupled with the wavelength selective filter 900, and at the same time, should be in thermal contact with an upper plate of the thermoelectric cooler 500 to make the temperature of the entire wavelength selective filter 900 uniform. In this case, the adhesive used may also use epoxy containing silver, copper, and carbon nano tube.

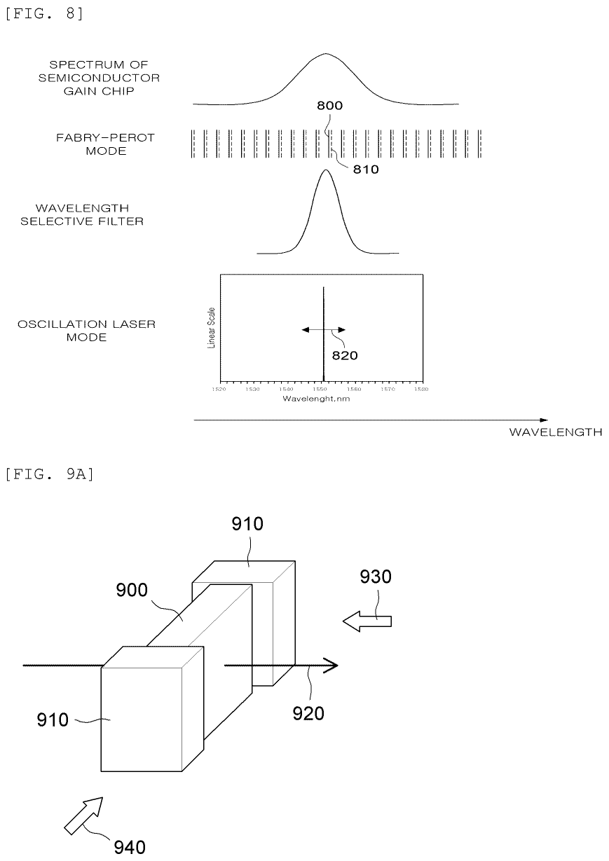

Accordingly, by not transferring the upper heat to the wavelength selective filter 900 or minimizing the transfer, the temperature change according to the position of the wavelength selective filter 900 described above in FIGS. 6 and 7 may be eliminated, thereby preventing the line width from increasing. In other words, according to the present disclosure, by applying the heat transfer member 910, the temperature of the wavelength selective filter 900 may be made uniform, and thus, since the wavelength of light transmitting the wavelength selective filter 900 does not vary depending on the location, there is an effect of narrowing the line width of the oscillation laser mode.

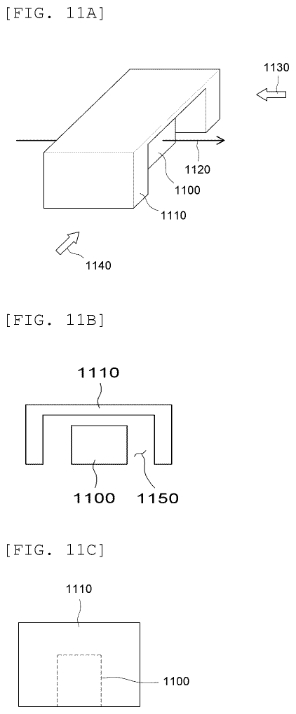

FIGS. 10A to 10C are diagrams for describing an external resonator-type laser including a heat transfer member arranged in a wavelength selective filter according to another embodiment of the present disclosure.

FIG. 10A is a perspective view of the wavelength selective filter and the heat transfer member, FIG. 10B is a front view of the wavelength selective filter and the heat transfer member as seen in a second direction 1030 in FIG. 10A, and FIG. 10C is a side view of the wavelength selective filter and the heat transfer member as seen in a third direction 1040 in FIG. 10A.

Referring to FIGS. 2, 10A, 10B, and 10C, light may transmit

a wavelength selective filter 1000 in a first direction 1020.

The heat transfer member may include two-sided heat transfer members 1010 and an upper heat transfer member 1015.

The two-sided heat transfer members 1010 are arranged on both side surfaces of the wavelength selective filter 1000 other than the wavelength selective filter 900 surface in the first direction 1020 which light transmits, and the lower side surface may be coupled with the thermoelectric cooler 500.

The upper heat transfer member 1015 may be arranged on the upper side surface of the wavelength selective filter 1000 other than the wavelength selective filter 1000 surface in the first direction 1020 which light transmits. The upper heat transfer member 1015 may be arranged only on the upper portion of the wavelength selective filter 1000, or may be arranged from the two-sided heat transfer members 1010 to the upper portion of the wavelength selective filter 1000.

In this case, the upper heat transfer member 1015 may be in thermal contact with the wavelength selective filter 900 and the two-sided heat transfer members 1010, and the attachment method may be applied in the same method as described in FIG. 9A.

In addition, the two-sided heat transfer members 1010 and the upper heat transfer member 1015 may be provided separately, or may be implemented in various ways such as being provided as an integral body.

In addition, the width of the two-sided heat transfer members 1010 and the upper heat transfer member 1015 may be the same as or larger than the width of the wavelength selective filter 1000.

The two-sided heat transfer members 1010 and the upper heat transfer member 1015 may be members having a better heat transfer rate than the wavelength selective filter 300. By using a material having a high heat transfer rate, the heat transferred from the upper portion may be transferred to a lower portion through the heat transfer member 910 rather than the wavelength selective filter 900.

According to the present embodiment, by further including the upper heat transfer member 1015, there is an additional effect of preventing the heat transferred from the upper side from being directly transferred to the wavelength selective filter 1000.

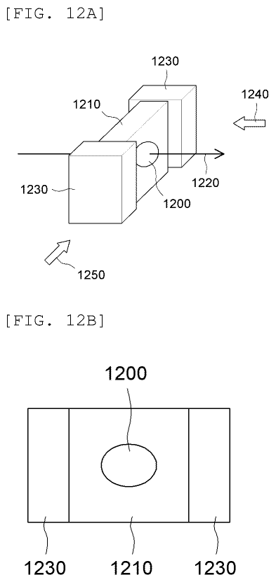

FIGS. 11A to 11C are diagrams for describing an external resonator-type laser including a heat transfer member arranged in a wavelength selective filter according to another embodiment of the present disclosure.

FIG. 11A is a perspective view of the wavelength selective filter and the heat transfer member, FIG. 11B is a front view of the wavelength selective filter and the heat transfer member as seen in a second direction 1130 in FIG. 11A, and FIG. 11C is a side view of the wavelength selective filter and the heat transfer member as seen in a third direction 1140 in FIG. 11A.

Referring to FIGS. 2, 11A, 11B, and 11C, light may transmit a wavelength selective filter 1100 in a first direction 1120.

The heat transfer member 1110 may be arranged to be spaced apart from the wavelength selective filter 110 while surrounding both side surfaces and the upper side surface of the wavelength selective filter 1100 other than the wavelength selective filter 1100 surface (‘the surface which light transmits’) in the first direction 1120 which light transmits, and the lower side surface may be coupled with the thermoelectric cooler 500.

In addition, the heat transfer member 1110 may be implemented in various ways, such as being provided as an integral type or being provided by attaching multiple members.

In addition, the width of the heat transfer member 1110 may be the same as or larger than the width of the wavelength selective filter 1100.

According to the present embodiment, since the heat transfer member 1110 is arranged to be spaced apart from the wavelength selective filter 1100, the heat transfer by heat radiation is blocked by an air layer formed to be spaced apart, thereby having the effect of blocking or alleviating the heat transferred to the wavelength selective filter 1100.

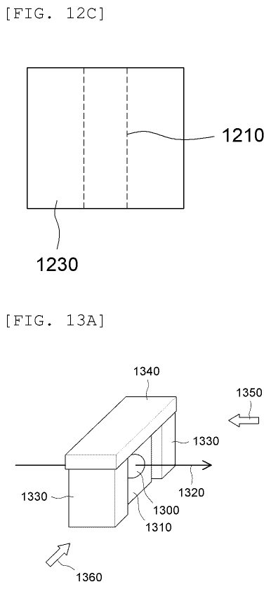

FIGS. 12A to 12C are diagrams for describing an external resonator-type laser including a heat transfer member arranged in a lens according to an embodiment of the present disclosure.

FIG. 12A is a perspective view of the lens and the heat transfer member, FIG. 12B is a front view of the lens and the heat transfer member as seen in a second direction 1240 in FIG. 12A, and FIG. 12C is a side view of the wavelength selective filter and the heat transfer member as seen in a third direction 1250 in FIG. 12A.

Referring to FIGS. 2, 12A, 12B, and 12C, light may transmit the lens 1200 in a first direction 1220.

The lens fixing member 1210 may be coupled with the lens 1200 so that the lens 1200 may be erected in a vertical direction relative to the thermoelectric cooler 500. The shape of the lens fixing member 1210 can be any shape that may erect the lens 1200.

The heat transfer member 1230 may include a side heat transfer member 1230. The side heat transfer member 1230 is arranged on both side surfaces of the lens 1200 or the lens fixing member 1210 other than the lens 1200 surface (‘the surface which light transmits’) in the first direction 1220 which light transmits, and the lower side surface may be coupled with the thermoelectric cooler 500 and may be a member having a higher heat transfer rate than the lens 1200 or the lens fixing member 1210. By using the material having the higher heat transfer rate, the heat transferred from the upper portion may be transferred to the lower portion through the heat transfer member 1230 rather than the lens fixing member 1210.

For example, a method of attaching the heat transfer member 910 to an outer circumferential surface of the lens fixing member 1210 may use epoxy containing powders such as silver, copper, and carbon nano tube. The heat transfer member 1230 should be thermally coupled with the lens fixing member 1210, and at the same time, should be in thermal contact with an upper plate of the thermoelectric cooler 500 to make the temperature of the entire lens 1200 uniform. In this case, the adhesive used may also use epoxy containing silver, copper, and carbon nano tube.

Accordingly, by not transferring the upper heat to the lens fixing member 1210 and the lens 1200 or minimizing the transfer, the temperature change according to the position of the lens 1200 described above in FIGS. 6 and 7 may be eliminated, thereby preventing the line width from increasing. In other words, according to the present disclosure, by applying the heat transfer member 1230, the temperature of the lens 1200 may be made uniform, and thus, since the wavelength of light transmitting the lens 1200 does not vary depending on the location, there is an effect of narrowing the line width of the oscillation laser mode.

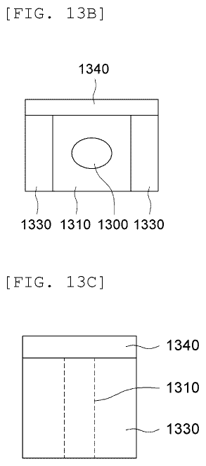

FIGS. 13A to 13C are diagrams for describing an external resonator-type laser including a heat transfer member arranged in a lens according to another embodiment of the present disclosure.

FIG. 13A is a perspective view of the lens and the heat transfer member, FIG. 13B is a front view of the lens and the heat transfer member as seen in a second direction 1350 in FIG. 13A, and FIG. 13C is a side view of the lens and the heat transfer member as seen in a third direction 1360 in FIG. 13A.

Referring to FIGS. 2, 13A, 13B, and 13C, light may transmit the lens 1300 in a first direction 1320.

The lens fixing member 1310 may be coupled with the lens 1300 so that the lens 1300 may be erected in a vertical direction relative to the thermoelectric cooler 500. The shape of the lens fixing member 1310 can be any shape that may erect the lens 1300.

The heat transfer member may include both-side heat transfer members 1330 and an upper heat transfer member 1340.

The two-sided heat transfer members 1330 are arranged on both side surfaces of the lens 1300 or the lens fixing member 1310 other than the lens 1300 surface in the first direction 1320 which light transmits, and the lower side surface may be coupled with the thermoelectric cooler 500.

The upper heat transfer member 1340 may be arranged on the upper side surface of the lens fixing member 1310 other than the lens 1300 surface in the first direction 1320 which light transmits. The upper heat transfer member 1340 may be arranged only on the upper portion of the lens fixing member 1310, or may be arranged from the two-sided heat transfer members 1330 to the upper portion of the lens fixing member 1310.

In this case, the upper heat transfer member 1340 may be in thermal contact with the lens fixing member 1310 and the two-sided heat transfer members 1330, and the attachment method may be applied in the same method as described in FIG. 9A.

In addition, the two-sided heat transfer members 1330 and the upper heat transfer member 1340 may be provided separately, or may be implemented in various ways such as being provided as an integral body.

In addition, the width of the two-sided heat transfer members 1330 and the upper heat transfer member 1340 may be the same as or larger than the width of the lens fixing member 1310. The two-sided heat transfer member 1330 and the upper

heat transfer member 1340 may be members having a higher heat transfer rate than the lens 1300 or the lens fixing member 1310. By using the material having the higher heat transfer rate, the heat transferred from the upper portion may be transferred to the lower portion through the heat transfer members 1330 and 1340 rather than the lens fixing member 1310 or the lens 1300.

According to the present embodiment, by further including the upper heat transfer member 1340, there is an additional effect of preventing the heat transferred from the upper portion from being transferred to the lens fixing member 1310 or the lens 1300.

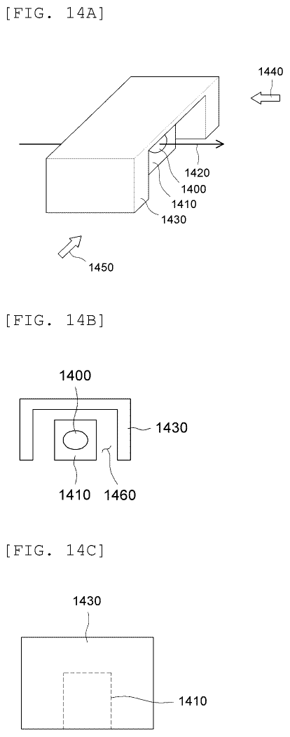

FIGS. 14A to 14C are diagrams for describing an external resonator-type laser including a heat transfer member arranged in a lens according to another embodiment of the present disclosure.

FIG. 14A is a perspective view of the lens and the heat transfer member, FIG. 14B is a front view of the lens and the heat transfer member as seen in a second direction 1440 in FIG. 14A, and FIG. 14C is a side view of the lens and the heat transfer member as seen in a third direction 1450 in FIG. 14A.

Referring to FIGS. 2, 14A, 14B, and 14C, light may transmit the lens 1400 in a first direction 1420.

The lens fixing member 1410 may be coupled with the lens 1400 so that the lens 1400 may be erected in a vertical direction relative to the thermoelectric cooler 500. The shape of the lens fixing member 1410 can be any shape that may erect the lens 1400.

The heat transfer member 1410 may be arranged to be spaced apart from the lens fixing member 1410 while surrounding both side surfaces and the upper side surface of the lens 1400 or the lens fixing member 1410 other than the lens 1400 surface (‘the surface through which light transmits’) in the first direction 1420 which light transmits, and the lower side surface may be coupled with the thermoelectric cooler 500.

In addition, the heat transfer member 1410 may be implemented in various ways, such as being provided as an integral type or being provided by attaching multiple members.

In addition, the width of the heat transfer member 1410 may be the same as or larger than the width of the lens fixing member 1410.

According to the present embodiment, since the heat transfer member 1110 is arranged to be spaced apart from the wavelength selective filter 1100, the heat transfer by heat radiation is blocked by an air layer formed to be spaced apart, thereby having the effect of blocking or alleviating the heat transferred to the wavelength selective filter 1100.

The methods of applying the heat transfer member applicable to the wavelength selective filter or lens described above may be applied to the wavelength selective filter or lens alone or in combination in various ways.

All or some of the respective embodiments may be selectively combined with each other so that the above-described embodiments may be variously modified.

In addition, it is to be noted that the embodiments are provided in order to describe the present disclosure rather than limiting the present disclosure. Further, it may be understood by those skilled in the art to which the present disclosure pertains that various embodiments are possible without departing from the spirit and scope of the present disclosure.

1. An external resonator-type laser having a narrow line width including a gain chip having a laser gain, a lens for collimating light emitted from the gain chip into parallel light and a wavelength selective filter for transmitting light having a specific wavelength among the light collimated through the lens comprising:
two-sided heat transfer members disposed on at least one side of at least one of the lens and the wavelength selective filter and made of a material having a higher heat transfer rate than the lens and the wavelength selective filter.

2. The external resonator-type laser of claim 1, further comprising:
an upper heat transfer member, which is arranged on an upper side surface of the lens and the wavelength selective filter and made of a material having the higher heat transfer rate than the lens and the wavelength selective filter.

3. The external resonator-type laser of claim 2, wherein the two-sided heat transfer members and the upper heat transfer member are arranged to be spaced apart from the lens and the wavelength selective filter to form a space.

4. The external resonator-type laser of claim 1, further comprising:
a lens fixing member coupled with the lens and having a structure that allows the lens to be erected in a vertical direction,
wherein the heat transfer member is arranged on a side surface portion of the lens fixing member.

5. The external resonator-type laser of claim 1, wherein the heat transfer member is made of a material having a heat transfer rate of 50 W/(m2° C.) or higher, and is made of a semiconductor material including one of silicon (Si), gallium arsenide (GaAs), and germanium (Ge), or a metal material including one of aluminum (Al) and copper (Cu).

6. The external resonator-type laser of claim 1, wherein the heat transfer member is attached through an epoxy mixed with powder including one or more of silver, copper, and carbon nanotube.

7. The external resonator-type laser of claim 1, wherein at least one of the gain chip, the lens, the wavelength selective filter, and the heat transfer member is arranged in thermal contact with a thermoelectric cooler.
